(19) United States
(12) Patent Application Publication
(10) Pub. No.: US 2026/0253620 A1
(43) Pub. Date: Aug. 27, 2026

(54) MEMORY ARRAY

(71) Applicant: XIAMEN INDUSTRIAL TECHNOLOGY RESEARCH INSTITUTE CO., LTD., Xiamen (CN)

(72) Inventors: Meidong LIU, Xiamen (CN); Yuhuang CHEN, Xiamen (CN); Juilung CHEN, Xiamen (CN); Tianhui HUANG, Xiamen (CN)

(73) Assignee: XIAMEN INDUSTRIAL TECHNOLOGY RESEARCH INSTITUTE CO., LTD., Xiamen (CN)

(21) Appl. No.: 18/994,087

(22) PCT Filed: Jun. 3, 2024
(86) PCT No.: PCT/CN2024/097063

§ 371 Date: Jan. 14, 2025

(30) Foreign Application Priority Data
Jun. 8, 2023 (CN) 202310674550.0

(51) Int. Cl. G11C 5/06; G11C 5/02; H10B 63/00

(52) U.S. Cl. CPC G11C 5/063; G11C 5/02; H10B 63/30; H10B 63/84

(57) ABSTRACT

Provided is a memory array. The memory array includes at least one main array and at least one dummy array, the main array is adjacent to the dummy array, at least one resistive memory cell of the dummy array shares a same bit line with at least one resistive memory cell of an adjacent main array; and the size of the at least one resistive memory cell of the dummy array is greater than that of the at least one resistive memory cell of the adjacent main array. The larger size of the resistive memory cell corresponds to lower forming voltage, making it easier to change from a high resistance state to a low resistance state. As such, the initial state of the resistive memory cell in the main array can be in the high resistance state, thereby improving the yield of the memory array.

### CROSS REFERENCE TO THE RELATED APPLICATIONS

The present application is based upon and claims priority to Chinese Patent Application No. 202310674550.0, filed with China National Intellectual Property Administration on Jun. 8, 2023, the entire contents of which are incorporated herein by reference.

### TECHNICAL FIELD

The present disclosure relates to the technical field of semiconductors, and in particular to a memory array.

### BACKGROUND TECHNOLOGY

In the related art, during the production process of a ReRAM memory array, due to the influence of plasma induced damage (PID) or other factors, some cells in an array are in a low resistance (LR) state and cannot be reset, which reduces the yield of a memory chip.

### CONTENT OF THE INVENTION

The present disclosure provides a memory array to solve at least the above technical problems in the related art.

A memory array provided in the present disclosure includes at least one main array and at least one dummy array;
the main array is adjacent to the dummy array;
at least one resistive memory cell of the dummy array shares a same bit line with at least one resistive memory cell of an adjacent main array; and
a size of the at least one resistive memory cell of the dummy array is greater than a size of the at least one resistive memory cell of the adjacent main array.

In the above solution, the at least one main array and the at least one dummy array may be both of 1T1R structures with one transistor corresponding to one resistive memory cell; and the at least one main array and the at least one dummy array may include at least two resistive memory cells respectively.

In the above solution, the main array and the dummy array may include four 1T1R structures respectively; a positive electrode of a resistive memory may be connected to a bit line, and a negative electrode of the resistive memory may be connected to a drain of a corresponding transistor; sources of two transistors corresponding to two resistive memories connected to a same bit line may be connected to each other; and gates of the two transistors corresponding to the two resistive memories connected to the same bit line may be connected to a first word line and a second word line respectively.

In the above solution, two 1T1R structures connected to the same bit line may be set as a group of 1T1Rs, and positive electrodes of two resistive memories contained in a same group of 1T1Rs may be connected to the same bit line.

In the above solution, the at least one resistive memory cell of the dummy array sharing the same bit line with the at least one resistive memory cell of the adjacent main array may include: positive electrodes of two resistive memory cells contained in a first group of 1T1R structures of the dummy array, and a positive electrode of at least one resistive memory cell contained in a first group of 1T1R structures of the at least one main array corresponding to the dummy array, may be connected to a first bit line; and positive electrodes of two resistive memory cells contained in a second group of 1T1R structures of the dummy array, and a positive electrode of at least one resistive memory cell contained in a second group of 1T1R structures of the at least one main array corresponding to the dummy array, may be connected to a second bit line.

In the above solution, in the main array and the dummy array, a gate of a first transistor in a first group of 1T1Rs and a gate of a first transistor in a second group of 1T1Rs may be connected to a first word line; and in the main array and the dummy array, a gate of a second transistor in the first group of 1T1Rs and a gate of a second transistor in the second group of 1T1Rs may be connected to a second word line.

In the above solution, in the main array and the dummy array, sources of a first transistor and a second transistor in a first group of 1T1Rs may be connected to a source line; and in the main array and the dummy array, sources of a first transistor and a second transistor in a second group of 1T1Rs may be connected to the source line.

In the above solution, the dummy array may be of a structure with one diode corresponding to one resistive memory cell; and the transistor may be the diode, and a negative electrode of the diode may be connected to a negative electrode of the resistive memory cell.

In the above solution, in a forming process, when charges on a bit line accumulate to a preset value, the resistive memory cell in the dummy array may change from a high resistance state to a low resistance state, the charges on the bit line may be released from the resistive memory cell and a parasitic diode on the transistor in the dummy array, and an initial state of the resistive memory cell in the adjacent main array is the high resistance state.

In the above solution, a distance between the at least one main array and the adjacent dummy array may be less than a preset threshold.

The memory array of the present disclosure includes at least one main array and at least one dummy array, the main array is adjacent to the dummy array, at least one resistive memory cell of the dummy array shares a same bit line with the resistive memory cell(s) of an adjacent main array; and the size of the at least one resistive memory cell of the dummy array is greater than that of the resistive memory cell of the adjacent main array. The larger size of the resistive memory cell corresponds to lower forming voltage, making it easier to change from a high resistance state to a low resistance state. In two adjacent resistive memory cells, when one is in the low resistance state, the other cannot be in the high resistance state; as such, the initial state of the resistive memory cell in the main array can be in the high resistance state, thereby improving the yield of the memory array.

It should be understood that the content described in this section is not intended to identify critical or important features of the embodiments of the present disclosure, and is not used to limit the scope of the present disclosure either. Other features of the present disclosure will be easily understood through the following description.

### DESCRIPTION OF THE DRAWINGS

By reading the following detailed description with reference to the accompanying drawings, the above and other objectives, features and advantages of the exemplary embodiments of the present disclosure will become easier to understand. In the drawings, several embodiments of the present disclosure are shown in an exemplary and non-limiting manner.

In the drawings, the same or corresponding reference numerals denote the same or corresponding parts.

FIG. 1 illustrates a structure of a 1T1R resistive memory in the related art.

FIG. 2 illustrates a schematic diagram of a DC characteristic curve of a 1T1R ReRAM in the related art.

FIG. 3 illustrates a first schematic diagram of a memory array.

FIG. 4 illustrates a second schematic diagram of a memory array.

FIG. 5 illustrates an optional schematic diagram of a memory array provided in an embodiment of the present disclosure.

FIG. 6 illustrates another optional schematic diagram of a memory array provided in an embodiment of the present disclosure.

FIG. 7 illustrates a first schematic diagram of the relationship between the size of resistive memory cells and the forming voltage.

FIG. 8 illustrates a second schematic diagram of the relationship between the size of resistive memory cells and the forming voltage.

FIG. 9 illustrates a schematic diagram of the relationship between the size of resistive memory cells and an initial low resistance state.

FIG. 10 illustrates a schematic diagram of a test structure provided in an embodiment of the present disclosure.

FIG. 11 illustrates a first schematic diagram of test results provided in an embodiment of the present disclosure.

FIG. 12 illustrates a second schematic diagram of test results provided in an embodiment of the present disclosure.

FIG. 13 illustrates a schematic diagram of charges of a memory array provided in an embodiment of the present disclosure.

FIG. 14 illustrates a schematic diagram of another memory array provided in an embodiment of the present disclosure.

### SPECIFIC IMPLEMENTATIONS

In order to make the objectives, features, and advantages of the present disclosure more apparent and easier to understand, the technical solutions in the embodiments of the present disclosure will be clearly and completely described below with reference to the accompanying drawings in the embodiments of the present disclosure. Apparently, the described embodiments are merely a part rather than all of the embodiments of the present disclosure. On the basis of the embodiments in the present disclosure, all other embodiments obtained by those skilled in the art without any creative efforts shall fall within the protection scope of the present disclosure.

In the following description, the term “some embodiments” describes subsets of all possible embodiments, but it may be understood that “some embodiments” may be the same subset or different subsets of all the possible embodiments and may be combined with each other without conflict.

In the following description, the terms “first/second” merely distinguishes similar objects, and do not represent a specific order of the objects. It may be understood that the terms “first/second” may be interchanged in a specific order or a consecutive order, so that the embodiments of the present disclosure described here can be implemented in other order besides that illustrated or described here.

Unless otherwise defined, all technical and scientific terms used in the present disclosure have the same meanings as commonly understood by those skilled in the technical field of the present disclosure. The terms used in the present disclosure are only for the purpose of describing the embodiments of the present disclosure and are not intended to limit the present disclosure.

It should be understood that, in various embodiments of the present disclosure, the serial numbers of implementation processes do not mean the order of execution, and the order of execution of the processes should be determined by their functions and internal logics instead of any limitation on the implementation processes of the embodiments of the present disclosure.

Before embodiments of the present disclosure are further described in detail, the nouns and terms involved in the embodiments of the present disclosure are explained as follows.

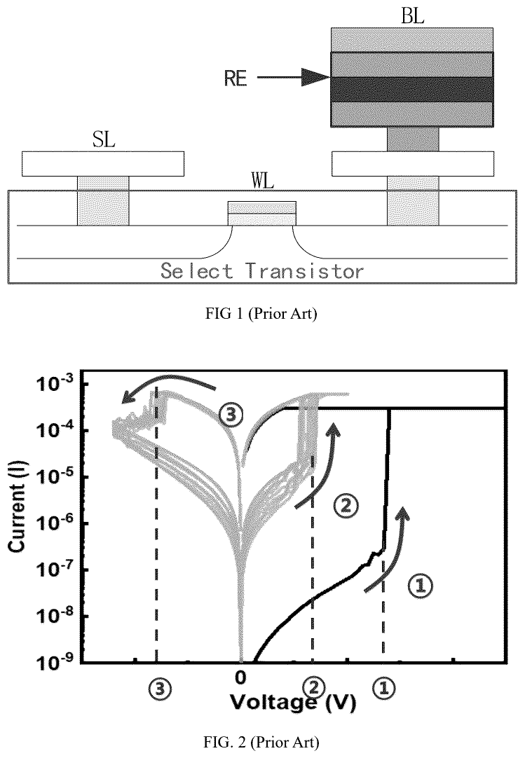

1T1R (one transistor one resistor) refers to a structure of a transistor corresponding to a resistive memory cell (ReRAM memory cell). FIG. 1 illustrates a structure of a 1T1R resistive memory in the related art.

As shown in FIG. 1, a memory resistor (RE) and a transistor form a 1T1R ReRAM memory cell. In FIG. 1, SL represents a source line, WL represents a word line, and BL represents a bit line. RE represents a resistive memory cell, and Select Transistor represents a select transistor, usually a diode or a field effect transistor (MOS).

FIG. 2 illustrates a schematic diagram of a direct current (DC) characteristic curve of a 1T1R ReRAM in the related art.

As shown in FIG. 2, the horizontal axis represents the difference between voltage at a bit line terminal (BL terminal) and voltage at a source line terminal (SL terminal), i.e. V_{BL}-V_{SL}, and the vertical axis represents current. In the horizontal axis, point \textcircled{1} represents forming voltage (V_{forming}), point \textcircled{2} represents set voltage (Vₛₑₜ), and point \textcircled{3} represents reset voltage (Vᵣₑₛₑₜ).
Curve \textcircled{1} represents a resistance value of the resistive memory cell in a forming process. It can be concluded according to curve \textcircled{1} that an initial state of the resistive memory cell is a high resistance state (HL). As V_{BL}-V_{SL} gradually increases to be greater than the forming voltage, the resistive memory cell changes to a low resistance state (LR).
Curve \textcircled{2}) represents a resistance value of the resistive memory cell in a set process. When the voltage increases to be greater than the set voltage, the resistance value of the resistive memory cell changes to the low resistance state.
Curve \textcircled{3} represents a resistance value of the resistive memory cell in a reset process. When the voltage decreases to be less than the reset voltage, the resistance value of the resistive memory cell changes to the high resistance state (HR).

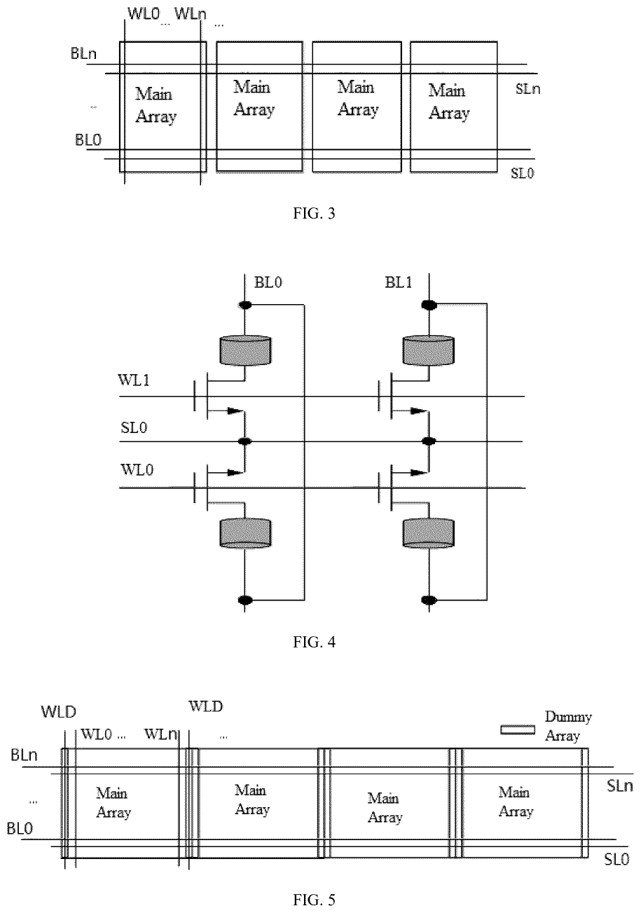

FIG. 3 illustrates a first schematic diagram of a memory array, and FIG. 4 illustrates a second schematic diagram of a memory array.

As shown in FIG. 3, main arrays are arranged adjacent to each other. As shown in FIG. 4, the main array includes four 1T1R structures, two 1T1R structures connected to a same bit line constitute one group, and one main array includes two groups.

In the related art, during the production process of a memory array, due to the influence of plasma induced damage (PID) and other factors, initial states of some cells in the array are in a low resistance (LR) state and cannot be reset, which reduces the yield of a memory chip.

This problem can be effectively solved from the perspectives of process and circuit:
\textcircled{1}) From the perspective of process, the manufacturing process for RE can be optimized; and \textcircled{2} from the perspective of circuit, an error checking and correcting (ECC) module can be added to correct failed cells, or a redundant module can be added to replace failed arrays.

The above methods solve the problem of initial low resistance state from the manufacturing level of underlying devices and the chip level separately. Embodiments of the present disclosure solve the problem of initial low resistance state from the array level.

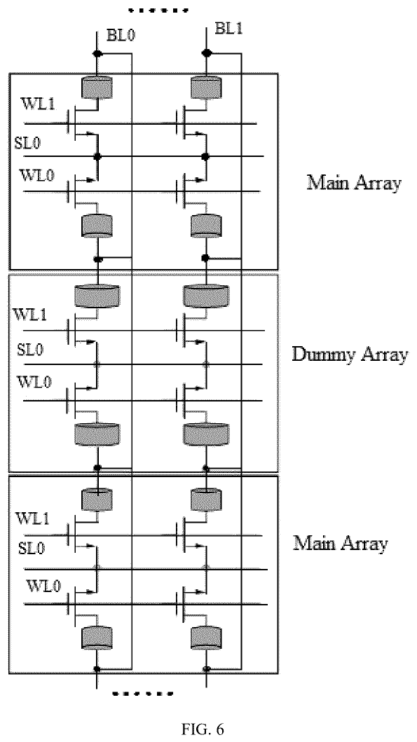

FIG. 5 illustrates an optional schematic diagram of a memory array provided in an embodiment of the present disclosure; FIG. 6 illustrates another optional schematic diagram of a memory array provided in an embodiment of the present disclosure.

As shown in FIG. 5, the memory array includes at least one main array and at least one dummy array; the main array is adjacent to the dummy array, that is, one dummy array is arranged between any two main arrays, and one dummy array is arranged between any two dummy arrays. Optionally, only the main arrays are arranged at edges, that is, the two main arrays at the edges are only adjacent to one dummy array. At least one resistive memory cell of the dummy array shares a same bit line with resistive memory cell(s) of an adjacent main array(s); and the size of the at least one resistive memory cell of the dummy array is greater than that of the resistive memory cell(s) of the adjacent main array(s). The size of the resistive memory cell may include a cross-sectional area of the resistive memory cell, such as square nanometers.

In some embodiments, the distance between the at least one main array and the adjacent dummy array is less than a preset threshold, and the preset threshold may be set according to actual needs or experimental results.

Specifically, as shown in FIG. 6, the at least one main array or the at least one dummy array may include one transistor corresponding to one resistive memory cell, i.e. a 1T1R structure; and the at least one main array or the at least one dummy array may include at least two resistive memory cells.

Assuming that both the main array and the dummy array include four 1T1R structures respectively, a positive electrode of the resistive memory is connected to a bit line, and a negative electrode of the resistive memory is connected to a drain (drain electrode) of a corresponding transistor; sources (source electrodes) of two transistors corresponding to two resistive memories connected to a same bit line are connected to each other; gates (gate electrodes) of the two transistors corresponding to the two resistive memories connected to the same bit line are connected to a first word line WL1 and a second word line WL0 respectively.

In some embodiments, for ease of description, two 1T1R structures connected to the same bit line are set as a group of 1T1Rs, and positive electrodes of two resistive memories contained in a same group of 1T1Rs are connected to the same bit line.

For example, in any array (main array or dummy array) in FIG. 6, two 1T1Rs vertically connected and disposed on the left side constitute one group, that is, in any array, two 1T1Rs connected to BLO constitute one group, and two 1T1Rs connected to BL1 constitute one group.

In some embodiments, at least one resistive memory cell of the dummy array shares the same bit line with the resistive memory cell(s) of the adjacent main array, as shown in FIG. 6. Any main array includes 2 groups of 1T1Rs, the dummy array also includes 2 groups of 1T1Rs, and 1 group of 1T1Rs in any main array (assuming the left group) and the corresponding 1 group of 1T1Rs in the dummy array (assuming the left group) are connected to BL0; furthermore, another group of 1T1Rs in the main array (assuming the right group) and another group of 1T1Rs in the dummy array (assuming the right group) are connected to BL1; as such, at least one resistive memory cell in the dummy array can be affected by the same voltage as the resistive memory cell in the adjacent main array. Furthermore, at least one resistive memory cell in the dummy array first changes to a low resistance state, which ensures that an initial state of the resistive memory cell in the main array is a high resistance state.

In some embodiments, positive electrodes of two resistive memory cells contained in a first group of 1T1R structures of the dummy array, and positive electrodes of two resistive memory cells contained in a first group of 1T1R structures of two main arrays corresponding to the dummy array, are connected to a first bit line BL0. Positive electrodes of two resistive memory cells contained in a second group of 1T1R structures of the dummy array, and positive electrodes of two resistive memory cells contained in a second group of 1T1R structures of the two main arrays corresponding to the dummy array, are connected to a second bit line BL1.

In some embodiments, transistors in both the main array and the dummy array are MOS transistors as an example for explaining the connection relationship between the transistors and the resistive memory cells in the main array or the dummy array.

In some embodiments, as shown in FIG. 6, a drain (D) of a first transistor and a drain of a second transistor in the first group of 1T1Rs in/of the dummy array are connected to negative electrodes of the two resistive memory cells in the first group of 1T1Rs respectively, and a drain of a first transistor and a drain of a second transistor in the second group of 1T1Rs in the dummy array are connected to negative electrodes of the two resistive memory cells in the second group of 1T1Rs respectively. In the main array and the dummy array, a gate (G) of the first transistor in the first group of 1T1Rs and a gate (G) of the first transistor in the second group of 1T1Rs are connected to a first word line WL1. In the main array and the dummy array, a gate of the second transistor in the first group of 1T1Rs and a gate of the second transistor in the second group of 1T1Rs are connected to a second word line WL0.

In the main array and the dummy array, sources(S) of the first transistor and the second transistor in the first group of 1T1Rs are connected to a source line SL0. In the main array and the dummy array, sources of the first transistor and the second transistor in the second group of 1T1Rs are connected to a source line SL0.

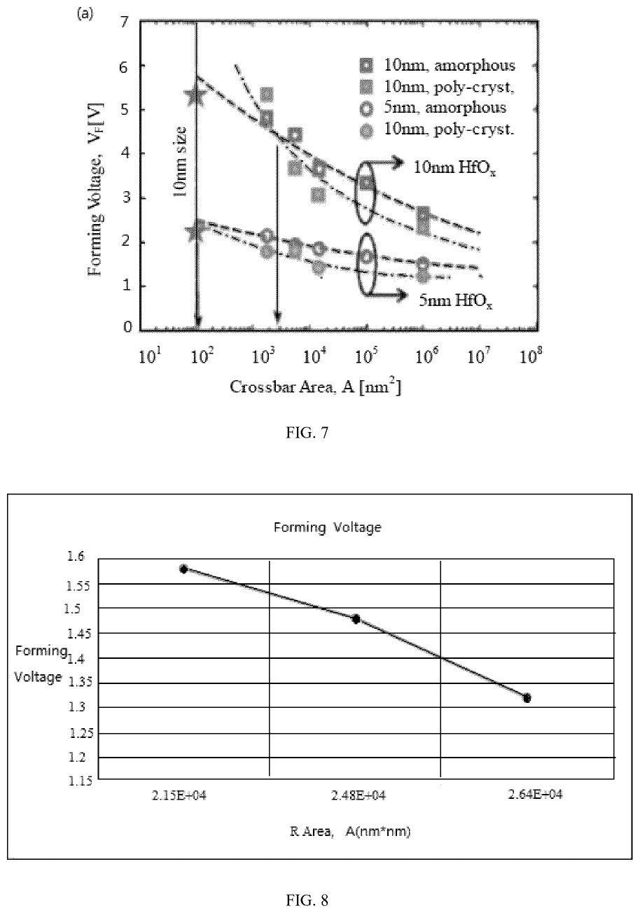

As shown in FIG. 6, the size of the resistive memory cell in the dummy array is greater than that of the resistive memory cell in the main array. FIG. 7 illustrates a first schematic diagram of the relationship between the size of resistive memory cells and the forming voltage, and FIG. 8 illustrates a second schematic diagram of the relationship between the size of resistive memory cells and the forming voltage. FIG. 7 and FIG. 8 show test results obtained under different experimental conditions.

As shown in FIG. 7, the horizontal axis represents the size of resistive memory cells in square nanometers (nm²), and the vertical axis represents the value of the forming voltage in volts (V). It can be concluded from FIG. 7 that, under same conditions, the larger the size of resistive memory cells, the lower the value of the corresponding forming voltage.

As shown in FIG. 8, the horizontal axis represents the size of resistive memory cells in square nanometers (nm²), and the vertical axis represents the value of the forming voltage in volts (V). It can be concluded from FIG. 8 that, under same conditions, the larger the size of resistive memory cells, the lower the value of the corresponding forming voltage.

FIG. 9 illustrates a schematic diagram of the relationship between the size of resistive memory cells and an initial low resistance state.

In FIG. 9, the horizontal axis represents the size of resistive memory cells in square nanometers, and the horizontal axis represents the probability (%) of initial low resistance state.

As shown in FIG. 9, the larger the size of resistive memory cells, the higher the probability of initial low resistance state.

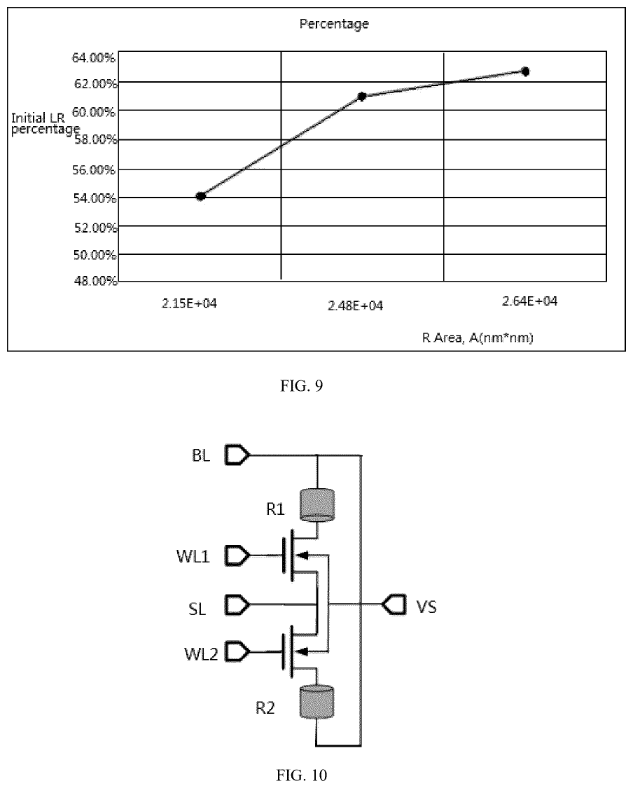

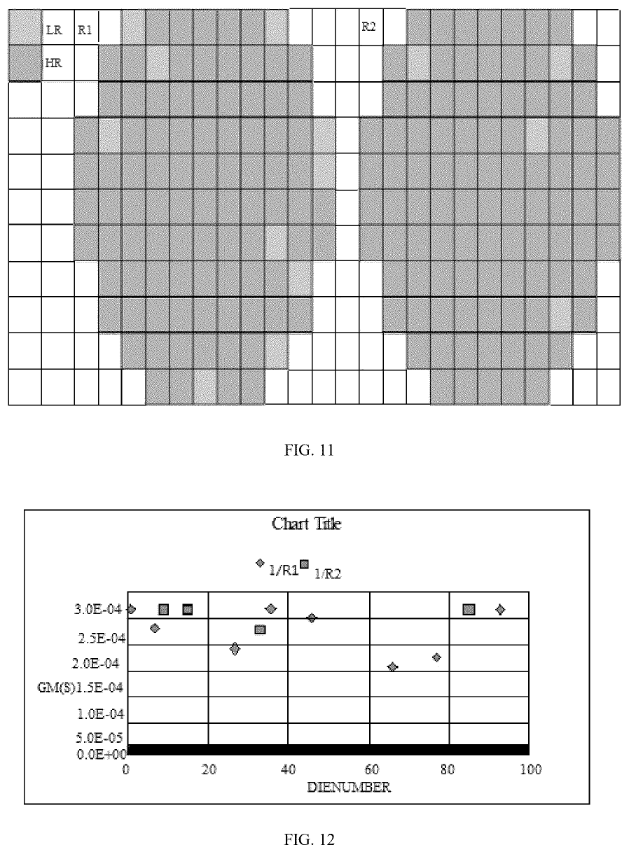

FIG. 10 illustrates a schematic diagram of a test structure provided in an embodiment of the present disclosure; FIG. 11 illustrates a first schematic diagram of test results provided in an embodiment of the present disclosure, and FIG. 12 illustrates a second schematic diagram of test results provided in an embodiment of the present disclosure.

As shown in FIG. 10, two resistive memory cells R1 and R2 to be tested are connected to a same bit line. As shown in FIG. 11, the left array is an array that constitutes the resistive memory cell R1, and each cell represents a resistance value of a corresponding resistor in the array. The right array shows an array that constitutes the resistive memory cell R2, and each cell represents a resistance value of a corresponding resistor in the array. It can be seen from FIG. 11 that there are no cells in the R1 array and the R2 array which are disposed in the same position and are in the same low resistance state, showing that for the resistive memory cells sharing the same bit line, the cells near the initial low resistance state are less likely to be in the low resistance state, and indirectly showing that in the resistive memory cells sharing the same bit line, if one resistive memory cell is in the initial low resistance state, the adjacent resistive memory cell is less likely to be in the initial low resistance state.

As shown in FIG. 12, each point represents admittance of a corresponding cell in the resistive memory cell. It can be seen from FIG. 12 that the admittances of R1 and R2 do not coincide, indirectly showing that in the resistive memory cells sharing the same bit line, if one resistive memory cell is in the initial low resistance state, the adjacent resistive memory cell is less likely to be in the initial low resistance state.

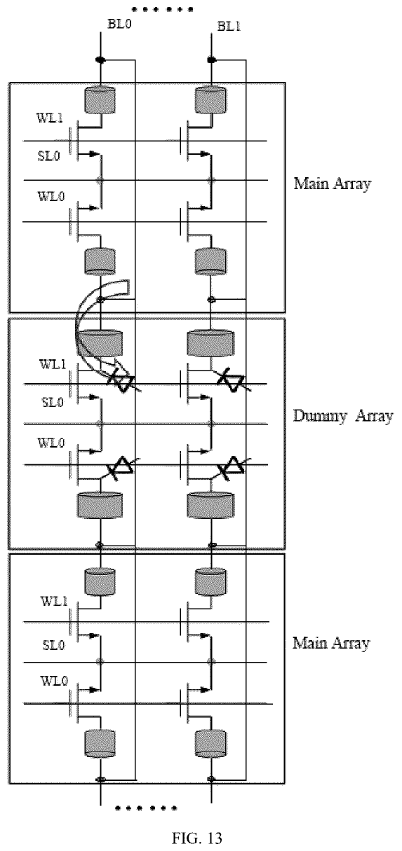

FIG. 13 illustrates a schematic diagram of charges of a memory array provided in an embodiment of the present disclosure.

According to the above conclusion, the size of the resistive memory cells in the dummy array is greater than that in the main array, and the forming voltage corresponding to the resistive memory cells in the dummy array is less than that in the main array, making it easier to form a charge release path on the same bit line. The probability that the resistive memory cells in the dummy array are in the initial low resistance state is greater than the probability that the resistive memory cells in the main array are in the initial low resistance state. In the resistive memory cells sharing the same bit line, if one resistive memory cell is in the initial low resistance state, the adjacent resistive memory cell is less likely to be in the low resistance state.

Furthermore, due to the larger size of the resistive memory cells in the dummy array, their forming voltage is low. When charges accumulate on the BL (BL0 or BL1) to a certain degree (such as a preset value, which may be set according to actual needs or experimental results), the resistive memory cell(s) in the dummy array first may change from a high resistance state to a low resistance state, making it easier to release the charges on the BL from the resistive memory cells and a parasitic diode(s) of the transistor(s) in the dummy array. After the charges on the BL are released, no threat is posed to the resistive memory cells in the main array, which can effectively protect the initial state of the resistive memory cells in the adjacent main array on the same BL in a high resistance state. As such, the resistive memory cells in the main array can be reset, which improves the yield of a storage chip.

Therefore, by using large-sized resistive memory cells as dummy arrays can effectively reduce the initial low resistance state (initial LR) ratio of the main arrays. The dummy array structure in the embodiments of the present disclosure can effectively reduce the initial low resistance state ratio of the main arrays.

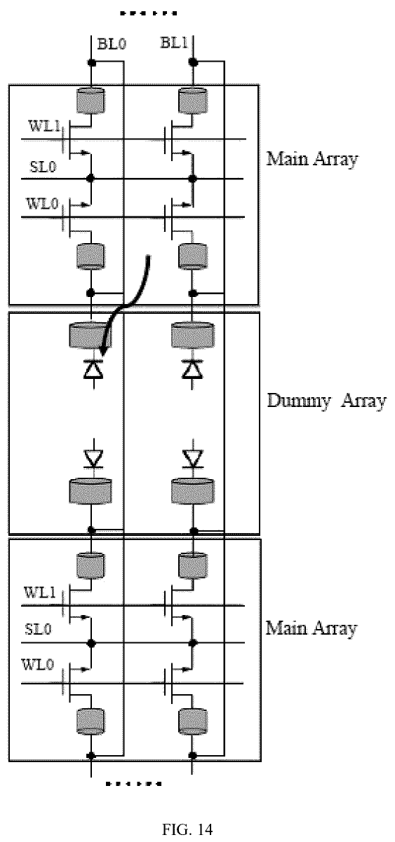

FIG. 14 illustrates a schematic diagram of another memory array provided in an embodiment of the present disclosure.

In the memory array shown in FIG. 14, the size and connection mode of the resistive memory cells in the dummy array are the same as those in FIG. 6 or FIG. 13, and will not be repeated here. The difference is that the transistors are replaced with diodes, and negative electrodes of the diodes are connected to positive electrodes of the resistive memory cells.

Due to the larger size of the resistive memory cells in the dummy array, their forming voltage is low. When charges accumulate on the BL (BL0 or BL1) to a certain degree, the resistive memory cells in the dummy array first change from a high resistance state to a low resistance state, making it easier to release the charges on the BL from the resistive memory cells and diodes in the dummy array. After the charges on the BL are released, no threat is posed to the resistive memory cells in the main array, which can effectively protect the resistive memory cells in the adjacent main array on the same BL in a high resistance state. As such, the resistive memory cells in the main array can be reset, which improves the yield of a storage chip.

It should be understood that the steps may be reordered, added or deleted using various forms of flows shown above. For example, the steps recorded in the present disclosure may be performed concurrently, in order, or in a different order, provided that the desired results of the technical solutions disclosed in the present disclosure can be achieved, which is not limited herein.

What are described above are merely specific embodiments of the present disclosure, and are not intended to limit the scope of protection of the present disclosure, and any changes or substitutions that can readily occur to those skilled in the art within the scope of technologies disclosed in the present disclosure should fall within the scope of protection of the present disclosure. Therefore, the scope of protection of the present disclosure shall be subject to the scope of protection of the claims.

What is claimed is:

1. A memory array, wherein the memory array comprises at least one main array and at least one dummy array;
the main array is adjacent to the dummy array;
at least one resistive memory cell of the dummy array shares a same bit line with at least one resistive memory cell of an adjacent main array; and
a size of the at least one resistive memory cell of the dummy array is greater than a size of the at least one resistive memory cell of the adjacent main array.

2. The memory array according to claim 1, wherein
the at least one main array and the at least one dummy array are both of 1T1R structures with one transistor corresponding to one resistive memory cell; and
the at least one main array and the at least one dummy array comprise at least two resistive memory cells respectively.

3. The memory array according to claim 2, wherein the main array and the dummy array comprise four 1T1R structures respectively;
a positive electrode of a resistive memory is connected to a bit line, and a negative electrode of the resistive memory is connected to a drain of transistor corresponding to the resistive memory;
sources of two transistors corresponding to two resistive memories connected to a same bit line are connected to each other; and
gates of the two transistors corresponding to the two resistive memories connected to the same bit line are connected to a first word line and a second word line respectively.

4. The memory array according to claim 3, wherein
two 1T1R structures connected to the same bit line are set as a group of 1T1R structures, and positive electrodes of two resistive memories contained in a same group of 1T1R structures are connected to the same bit line.

5. The memory array according to claim 4, wherein the at least one resistive memory cell of the dummy array sharing the same bit line with the at least one resistive memory cell of the adjacent main array comprises:
positive electrodes of two resistive memory cells contained in a first group of 1T1R structures of the dummy array, and a positive electrode of at least one resistive memory cell contained in a first group of 1T1R structures of the at least one main array corresponding to the dummy array, are connected to a first bit line; and
positive electrodes of two resistive memory cells contained in a second group of 1T1R structures of the dummy array, and a positive electrode of at least one resistive memory cell contained in a second group of 1T1R structures of the at least one main array corresponding to the dummy array, are connected to a second bit line.

6. The memory array according to claim 3, wherein
in the main array and the dummy array, a gate of a first transistor in a first group of 1T1R structures and a gate of a first transistor in a second group of 1T1R structures are connected to a the first word line; and
in the main array and the dummy array, a gate of a second transistor in the first group of 1T1R structures and a gate of a second transistor in the second group of 1T1R structures are connected to a second word line.

7. The memory array according to claim 3, wherein
in the main array and the dummy array, sources of a first transistor and a second transistor in a first group of 1T1R structures are connected to a source line; and
in the main array and the dummy array, sources of a first transistor and a second transistor in a second group of 1T1R structures are connected to the source line.

8. The memory array according to claim 1, wherein the dummy array is of a structure with one diode corresponding to one resistive memory cell; and
the transistor is the diode, and a negative electrode of the diode is connected to a negative electrode of the resistive memory cell.

9. The memory array according to claim 1, wherein
in a forming process, when charges on a bit line accumulate to a preset value, the resistive memory cell in the dummy array changes from a high resistance state to a low resistance state, the charges on the bit line are released from the resistive memory cell and a parasitic diode on the transistor in the dummy array, and an initial state of the resistive memory cell in the adjacent main array is the high resistance state.

10. The memory array according to claim 1, wherein a distance between the at least one main array and the adjacent dummy array is less than a preset threshold.

11. The memory array according to claim 8, wherein
in a forming process, when charges on a bit line accumulate to a preset value, the resistive memory cell in the dummy array changes from a high resistance state to a low resistance state, the charges on the bit line are released from the resistive memory cell and a parasitic diode on the transistor in the dummy array, and an initial state of the resistive memory cell in the adjacent main array is the high resistance state.
